(19) United States
(12) Patent Application Publication
(10) Pub. No.: US 2008/0067646 A1
(43) Pub. Date: Mar. 20, 2008

(54) SEMICONDUCTOR LEADFRAME FOR UNIFORM MOLD COMPOUND FLOW

(75) Inventor: John Paul Tellkamp, Denison, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/532,591

(22) Filed: Sep. 18, 2006

(51) Int. Cl. H01L 23/495

(52) U.S. Cl. 257/676

(57) ABSTRACT

A semiconductor device (400) with a plastic package (401) having on its surface (401a) a mark (402) identifying the location, where the runner for the molding compound was broken off. The device further exhibits a leadframe with a pad, which has a planar area (403) and a tab (404). The tab is bent at an angle (405) between 120° and 160°, preferably about 135°, towards the planar area and reaches a height (406) over the area. At least portions of the leadframe, including the pad and the tab, are encapsulated by the package; the tab (404) is parallel to the package side (401a) with the mark (402). The device has a semiconductor chip (410) attached to the pad; the thickness (411) of the chip is between 0.5 times and 1.0 times, preferably about 0.7 times, the tab height over the pad.

### FIELD OF THE INVENTION

The present invention is related in general to the field of semiconductor devices and processes and more specifically to leadframes for controlled methods of fabricating void-free semiconductor device packages.

### DESCRIPTION OF THE RELATED ART

For several decades, the transfer molding technology has been the preferred method of encapsulating semiconductor chips into plastic packages. Prior to the molding step, the chips are assembled on metallic leadframes with pads for attaching the chips. Over the years, the developments of device leadframes, mold equipment and molding compounds have been synchronized to provide fast, low cost process flows for fabricating robust and reliable products.

Recent market trends, however, for consumer-oriented products impose an abbreviated time-to-market for semiconductor devices. Due to the reduced time for development, chips of various thicknesses and/or areas frequently have to be assembled onto the same unchanged leadframes and encapsulated with the same unchanged molding compounds. In these cases, it is often observed that the finished packages exhibit huge voids of missing mold compound underneath the chip pads of the leadframes, causing package cracks and devices failures.

### SUMMARY OF THE INVENTION

Applicant recognizes the need to identify and correct the root cause of this assembly limitation and process sensitivity. Detailed observations reveal that the voids appear in packaged devices, where the package has been formed by an epoxy-based molding compound using the transfer molding technique. Specifically, the voids appear in devices with a leadframe designed for large area chips, but actually utilized for small area chips. Further, voids are observed in processes, where the leadframe position in the mold cavity had been selected for large chip thicknesses, but remains actually unchanged for much thinner chips.

As the applicant found, both the smaller chip size and the reduced chip thickness create a wider space on top of the assembled chip for the incoming compound, as compared to the narrower space provided underneath the chip pad. Consequently, the compound front can rush faster through the cavity along the top side of the assembled chip, compared to the slower compound front along the bottom cavity space. In turn, the higher velocity of the top front allows the top compound to exert pressure against the chip so that chip and chip pad are moved downward, hindering the progress of the bottom compound front even more. After the top cavity is filled with compound and the compound top movement stops, the downward pressure on the pad is released and the pad tries to snap back into its original position. However, since the compound has started to polymerize, the bottom compound is too stiff to follow the snap-back movement. Instead, the compound cohesion is ruptured and a void is formed.

One embodiment of the invention is a semiconductor device with a plastic package; one side of the package shows a mark (a “navel”) identifying the location, where the molding compound in the runner of the mold was broken off. The device further exhibits a leadframe with a pad, which has a planar area and a tab. The tab is bent at an angle between 120° and 160°, preferably about 135°, towards the planar area, and reaches a height over the area. The tab is parallel to the package side, which exhibits the surface mark. The device has a semiconductor chip attached to the pad; the thickness of the chip is between 0.5× and 1.0×, preferably about 0.7×, the tab height over the pad.

Another embodiment of the invention is a semiconductor device with a plastic package, which has sides and a corner formed by two adjacent sides; the corner has a surface mark. The surface mark identifies the location, where the runner for the molding compound was broken off. The device further includes a leadframe with a pad, which has a planar area and two tabs. The tabs are bent at an angle between 120° and 160°, preferably about 135°, towards the planar area, and reach a height over the area. The tabs are parallel to the two adjacent package sides of the corner, which exhibits the surface mark. The device has a semiconductor chip attached to the pad; the thickness of the chip is between 0.5× and 1.0×, preferably about 0.7×, the tab height over the pad.

Another embodiment of the invention is a method for fabricating a semiconductor device. A leadframe is provided, which has a pad including a planar area and a tab bent at an angle towards the area and reaching a height over the area. The preferred angle is about 135° relative to the planar pad. Further, a semiconductor chip with a thickness is provided; the chip is then attached to the leadframe pad. A mold apparatus is provided; the mold has a cavity firmed by sides and a gate at one of the sides. The leadframe is loaded into the cavity so that the tab is oriented parallel to the side with the gate and the chip, attached to the leadframe, separates the cavity into a top and a bottom half. Molding compound is pressured through the gate so that it progresses in flow fronts through the cavity, whereby the tab approximately equalizes the fronts flowing through the top and the bottom cavity half.

It is a technical advantage of the invention that it is the leadframe tab, facing the mold compound flow at an angle (preferably at right angle), which controls the mold flow. The molding process thus becomes tolerant to a wide range of chip sizes and chip thicknesses without any undesirable side effects such as the formation of voids in the polymerizing compound.

It is another technical advantage of the invention that it supports the trend towards leadframe standardization. The method is simple and low-cost, applicable to small-chip and large-chip semiconductor products, and to multi-chip assemblies on a leadframe pad. At the same time, the method is flexible and can be applied to a wide spectrum of material and process variations, leading to improved semiconductor device reliability.

The technical advances represented by the invention, as well as the aspects thereof, will become apparent from the following description of the preferred embodiments of the invention, when considered in conjunction with the accompanying drawings and the novel features set forth in the appended claims.

### BRIEF DESCRIPTION OF THE DRAWINGS

FIG. 1 illustrates schematically a cross section of a mold with a gate, a large or a medium-size semiconductor chip assembled on a pad having features according to the invention, and the resulting symmetrical molding compound flow independent of chip size.

FIG. 2 illustrates schematically a cross section of a mold with a gate, a large or a small-size semiconductor chip assembled on a pad having features according to the invention, and the resulting symmetrical molding compound flow independent of chip size.

FIG. 3 depicts a top view X-ray photograph of a leadframe for a dual-inline package inside a mold cavity; the arrows illustrate schematically the flow of the molding compound, which enters the cavity through the gate.

FIG. 4 is a schematic cross section of a finished molded dual-in-line (or surface mount) device with a leadframe according to an embodiment of the invention.

FIG. 5 is a schematic top X-ray view of a QuadFlatPak device with a leadframe according to an embodiment of the invention.

### DETAILED DESCRIPTION OF THE PREFERRED EMBODIMENTS

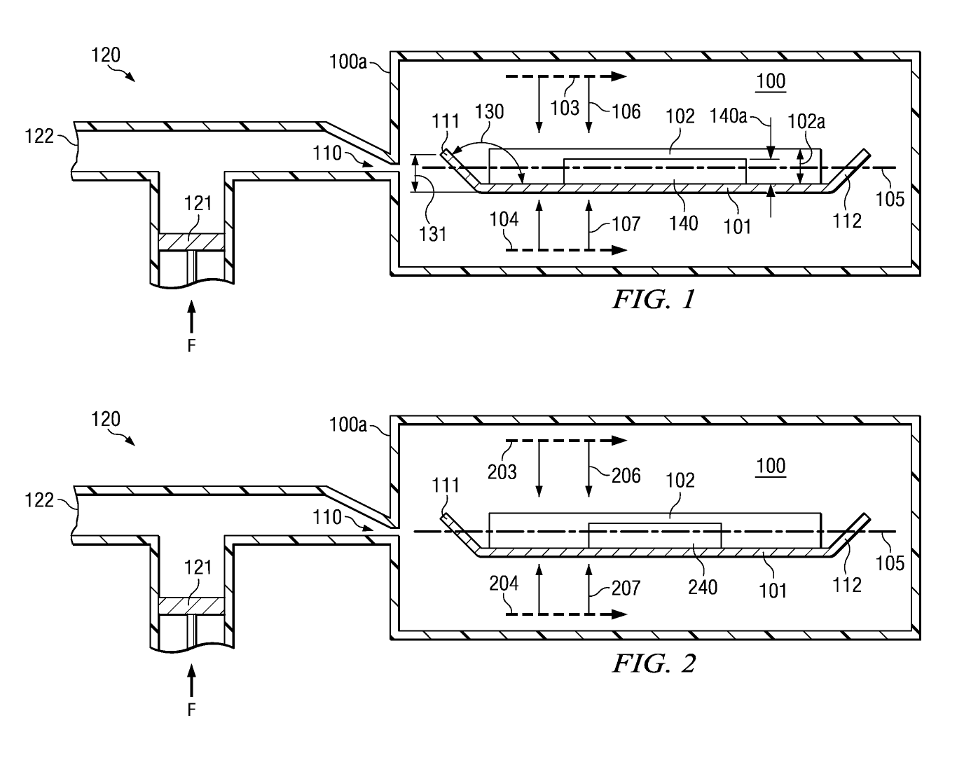

FIG. 1 illustrates schematically a mold cavity 100 as used for fabricating a molded semiconductor device with a leadframe according to an embodiment of the invention, which causes a balancing of the compound flows progressing through the top half and the bottom half of a mold in the transfer molding technology. Mold cavity 100 is connected through gate 110 to a runner system generally designated 120, which is filled with mold compound and delivers the compound into the cavity through gate 110. Force F presses moveable piston 121 against the compound so that the compound is squeezed into runners 122 and then through gate 110 into the cavity 100. It is preferred that the transfer pressure caused by force F is initially between 50 and 80 kg/cm² and finally between 15 to 30 kg/cm². The flow rate is controlled by the force F, the lengths and cross sections of the runners, the cross section of the gates, the temperature of the transfer operation (between 140 and 220° C., preferably about 175° C.), and the viscous and flow characteristics of the compound (preferably in the range from 30 to 200 poise). The compound is preferably epoxy-based and contains inorganic fillers (median filler sizes preferably form 15 to 25 μm); the transfer time is preferably between 5 and 18 s, and the polymerization time preferably between 70 and 120 s.

As indicated in FIG. 1, a semiconductor assembly is positioned inside cavity 100. The assembly includes a leadframe and an attached semiconductor chip. Actually, FIG. 1 illustrates only the leadframe pad with its planar area 101 and the tabs 111 and 112, and a semiconductor chip 102; other leadframe portions, such as the lead segments, are not shown in FIG. 1. The leadframe is preferably made from a sheet of copper or copper alloy in the thickness range from about 100 to 250 μm. Alternatively, the leadframe may be made of aluminum, aluminum alloy, iron-nickel alloy, or Kovar.

The embodiment of FIG. 1 has one tab at each opposing side of planar portion 101. However, according to the invention, tab 111 is adequate for controlling the mold compound flow. Tabs 111 and 112 are bent at an angle 130 towards planar portion 101. Angle 130 is preferably between about 120° and 160° relative to the planar tab; more preferably, angle 130 is about 135° relative to the planar pad. Tabs 111 and 112 reach a height 131 over the planar portion 101; height 131 is related to the thickness 102a of the chip attached to the leadframe pad. Preferably, tab height 131 is 1 times to 2 times chip thickness 102a; more preferably, the tab height is about 1.4 times chip thickness. Expressing this relation inversely, the chip thickness is between 1 times and 0.5 times tab height over the planar pad, preferably about 0.7 times tab height over the planar pad.

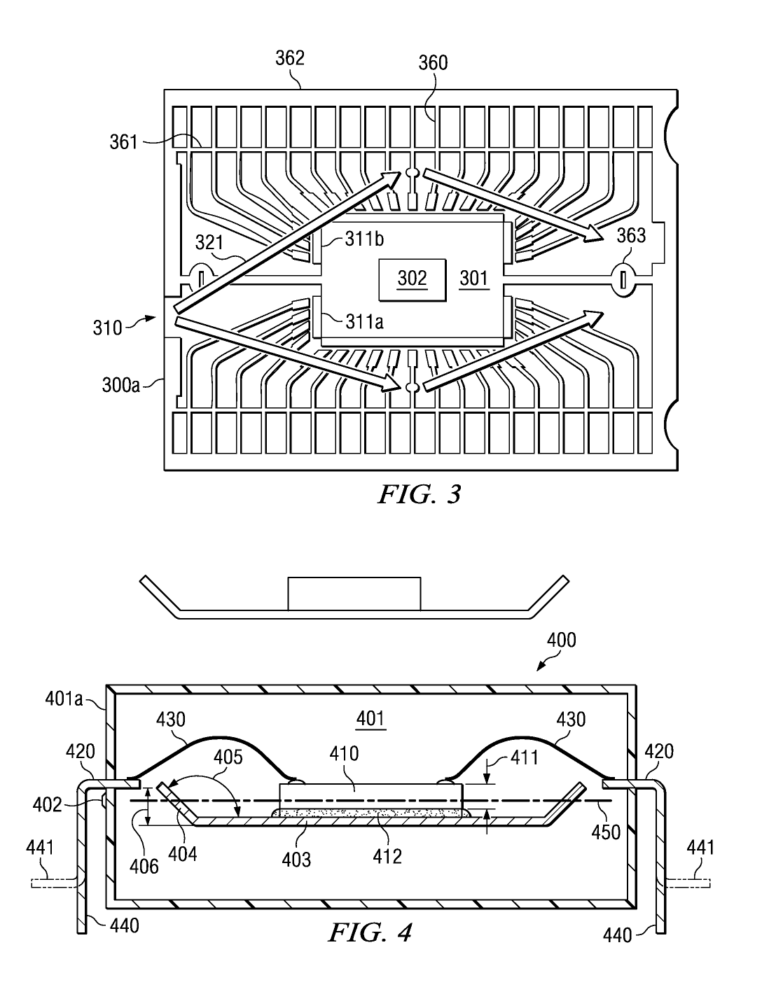

Leadframe tab 111 is oriented substantially parallel to the mold side 100a, which includes the gate 110. This fact is illustrated in the top view of FIG. 3, which shows the leadframe tab parallel to the mold side 300a having gate 310 (the tab is depicted in FIG. 3 as having two portions 311a and 311b because of the particular design of the leadframe pad straps for this device type).

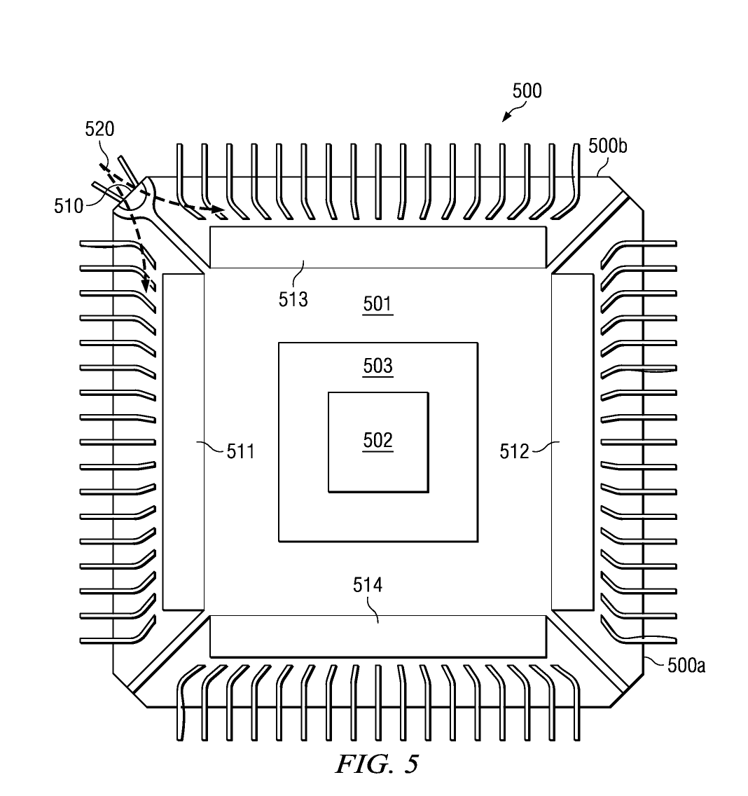

FIG. 1 illustrates the preferred position of leadframe pad 101 and attached chip 102 inside the mold cavity. The pad and the attached chip separate the cavity into a top and a bottom half, which have preferably about equal width. This chip-and-pad position is particularly favorable for many dual-in-line and QuadFlatPak devices. With this arrangement, and with the fact that tab 111 is substantially parallel to mold side 100a, tab 111 acts as an impediment and a regulator to the flow of the molding compound entering the cavity 100 through gate 110. In FIG. 1, the compound flow during the molding process is symbolized by arrow 103 in the top mold half and by arrow 104 in the bottom mold half. Some embodiments of the controlling effect of tab 111 are illustrated in the top views of FIGS. 3 and 5.

In molds with the gate located at one side of the cavity, as illustrated in FIG. 1, one single tab 111 located close to gate 110 (facing gate 110) is sufficient to accomplish the balancing effect on the mold compound flow during the molding process. However, in order to facilitate the chip attachment process, it has been found useful to employ a second tab 112 remote from gate 110, but also parallel to mold side 100a. Consequently, in molds with the gate at one side of the cavity, at least one leadframe tab is parallel to the side. In molds, however, with the gate at a corner of the mold cavity, at least two tabs are parallel to two sides. An embodiment is depicted in FIG. 5 for QuadFlatPak (QFP) devices.

The schematic X-ray picture of FIG. 5 highlights the leadframe and attached chip. The leadframe has a planar pad 501 with an area large enough for semiconductor chips of a variety of sizes. In FIG. 5, an example is the small chip 502, another example the somewhat larger chip 503.

The leadframe pad is positioned in a mold cavity 500, which has the gate 510 in a corner of the cavity. Adjacent to gate 500 are the cavity sides 500a and 500b. Planar pad 501 has tabs on all four sides. Tabs 511 and 512 are parallel to cavity side 500a, while tabs 513 and 514 are parallel to cavity side 500b. The tabs are bent at an angle and reach a height over the planar pad analogous to the description of the leadframe in FIG. 1.

FIG. 5 further indicates how the flow of mold compound 520, entering through gate 510 located in a corner of the mold cavity and progressing through the top half of the cavity, is affected by the tabs of the leadframe. Due to the orientation of tabs 511 and 513 relative to the location of gate 510, the tabs act as an angled impediment to the flow of the molding compound, effectively regulating the flow so that it progresses independent of the actual size of the chips attached to the planar pad. Consequently, the compound flow remains balanced in the top mold half containing the assembled chip, independent of the chip size; it can thus also be balanced relative to the compound flow in the bottom mold half, as illustrated in FIG. 1.

Referring to FIG. 1, illustrated are two assembly cases for mold cavity 100. In the first assembly case, a semiconductor chip 102 with a thickness 102a is attached to the planar chip pad 101 of the leadframe. In this case, the length of chip 102 is almost equal to the length of planar pad 101, and the height 131 of tab 111 is approximately 1 times chip thickness 102a. In the second assembly case shown in FIG.1, alternative chip 140 with a thickness 140a is attached to the planar pad 101. Chip 140 has a length smaller than the pad length. Thickness 140a is smaller than thickness 102a. In this case, height 131 of tab 111 is about 1.4 times thickness 140a of chip 140.

As FIG. 1 indicates, chip 102 (or chip 140) is attached to planar pad 101. The adhesive epoxy-based attach material is not shown in FIG. 1, nor is the electrical connection using bonding wires. The chip-on-leadframe assembly is then placed into cavity 100 so that tab 111 is parallel to mold side 100a; tab 111 faces gate 110, and chip 102 (or chip 140) separates cavity 100 into a top and a bottom half. Chip 402 (or chip 140) lays about in the centerline 105 of the cavity.

Next, molding compound is pressured through gate 110, where the flow front faces tab 111, angled to impede the flow. Consequently, the flow front progresses through cavity 100 substantially equalized in the top cavity half and the bottom cavity half, as indicated by the equal length of the flow arrows 103 and 104. The equalized flow fronts do not sense, whether the larger chip 102 or the smaller chip 140 is attached to pad 102; the fronts are independent of the length or thickness of the assembled chip, since the fronts are determined by the angled tab.

As a result of the equalized compound flow, pressure 106 on the assembly, exerted by flow 103, and pressure 107, exerted by flow 104, have substantially equal magnitude. Consequently, any displacement, and thus any snap-back of leadframe pad 111 is minimized. As a result, a disruption of the polymerizing compound is strongly reduced; the formation of a void in the polymerized compound is thus unlikely.

Based on the angled tab 111 (or angled tabs 111 and 112) of the leadframe pad, the flow of the mold compound is substantially uniform, even when the chip actually attached to the pad is significantly smaller, or thinner, or both, compared to the chip dimensions originally intended for attachment to the pad. This beneficial result of the invention is illustrated in FIG. 2. Chip 240 has a length significantly smaller than the length of chip 102 and pad 101; the thickness of chip 240 is also smaller than the thickness of chip 102. Due to angled tab 111, however, the compound flow 203 in the upper cavity half and flow 204 in the bottom cavity half are substantially equal. Pressures 206 and 207 are also about equal, resulting in approximately undisturbed position of the assembly during the molding process and substantial avoidance of void formation.

The magnified top view X-ray picture of FIG. 3 shows an embodiment of the invention for a 38-pin dual-in-line package. The view from top indicates a relatively small chip 302 attached to the center portion of the relatively larger pad 301 of the leadframe. The 38-lead segments 360 are arranged around the perimeter of pad 301 and continue to the dam-bars 361 and the rails 362 of the leadframe; the two pad straps 363 hold pad 301 to the rails (the bond wires connecting the chip to the segments are not shown).

As FIG. 3 shows, pad 301 has bent tabs on all four sides of its periphery. The two tab portions designated 311a and 311b are parallel to the mold side 300a having gate 310. After breaking off the mold compound in the runner from the mold compound of the device package, the location of gate 310 is clearly identified by the surface mark of the polymerized mold compound. Tab portions 311a and 311b have counterparts on the opposing side of tab 301; these counterparts are also parallel toe mold side 300a.

The arrows 321 schematically indicate the approximate direction and magnitude of the compound fronts during their movements through the top half of the mold cavity. Tabs 311a and 311b are effective in diverting the compound flow front into a detour, indicated by the arrows, thus slowing the otherwise quick shortcut across chip 302. As a result, the impediment of tabs 311a and 311b approximately equalizes the compound flow across the chip side of the leadframe in the top mold half to the compound flow across the bottom side of the leadframe in the bottom mold half (bottom flow not shown in FIG. 3).

Another embodiment of the invention, exemplified in FIG. 4, is a semiconductor device generally designated 400. The device can be a dual-in-line device (lead shape 440) or a surface-mount device (lead shape 441), dependent on the shape of its external lead segments. The device includes a package made of a plastic compound 401, such as an epoxy-based molding compound. The surface 401a of the package has a mark 402, which identifies the break-off location of the compound in the mold runner. The mark thus identifies the location of the gate in the mold apparatus, through which the mold compound had entered from the runner into the cavity.

The device 400 further includes a leadframe, which has a pad including a planar area 403 and a tab 404; FIG. 4 shows an additional tab on the opposing side of the pad area. Tab 404 is bent at an angle 405 towards the planar area and reaches a height 406 over the planar area. Tab angle 405 is preferably between 120° and 160°, and more preferably about 135°, relative to the planar pad. Tab 404 is oriented parallel to the package side 401a with the surface mark 402. As FIG. 4 shows, planar pad 403 and bent tab 404 are encapsulated by the molding compound 401.

Device 400 further includes a semiconductor chip 410, which has a thickness 411. Chip 410 is attached to the pad 403 with an adhesive material 412. Chip thickness 411 and tab height 406 are correlated. Preferably, the chip thickness is between 1 times and 0.5 times tab height; or expressed differently, the tab height is between 1 times and 2 times chip thickness. More preferably, the chip thickness is about 0.7 times tab height, or expressed differently, the pad height is about 1.4 times chip thickness. As the centerline 440 in FIG. 4 shows, chip 410, attached to leadframe pad 403, separates the molded package into a top and a bottom half, which have approximately equal widths.

Chip 410 is connected to the segments ends 420 inside the encapsulation by bonding wires 430.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description.

It is therefore intended that the appended claims encompass any such modifications or embodiments.

I claim:

1. A semiconductor device comprising:
a package made of a plastic compound, the package having a side including a surface mark;
a leadframe having a pad including a planar area and a tab bent at an angle towards the planar area and reaching a height over the planar area, the tab being parallel to the package side; and
a semiconductor chip having a thickness, the chip attached to the pad.

2. The device according to claim 1 wherein the surface mark identifies the break-off location of the mold compound in the mold runner.

3. The device according to claim 1 wherein the leadframe pad has a tab on opposing sides of the pad area.

4. The device according to claim 1 wherein the tab angle is between about 120° and 160° relative to the planar pad.

5. The device according to claim 1 wherein the tab angle is about 135° relative to the planar pad.

6. The device according to claim 1 wherein the chip thickness is between 1 times and 0.5 times tab height over the planar pad.

7. The device according to claim 1 wherein the chip thickness is about 0.7 times tab height over the planar pad.

8. A semiconductor device comprising:
a package made of a plastic compound, the package having sides and a corner formed by two adjacent sides, the corner including a surface mark;
a leadframe having a pad including a planar area and two tabs bent at an angle towards the planar area and reaching a height over the area, the tabs being parallel to the two adjacent package sides of the corner; and
a semiconductor chip having a thickness, the chip attached to the pad.

9. The device according to claim 8 wherein the surface mark identifies the break-off location of the mold compound in the mold runner.

10. The device according to claim 8 wherein the leadframe pad has a tab on each side of the pad area.

11. The device according to claim 8 wherein the tab angle is between about 120° and 160° relative to the planar pad.

12. The device according to claim 8 wherein the tab angle is about 135° relative to the planar pad.

13. The device according to claim 8 wherein the chip thickness is between 1 times and 0.5 times tab height over the pad.

14. The device according to claim 8 wherein the chip thickness is about 0.7 times tab height over the pad.

15. A method for fabricating a semiconductor device comprising the steps of:
providing a leadframe having a pad including a planar area and a tab bent at an angle towards the area and reaching a height over the area;
providing a semiconductor chip having a thickness;
attaching the chip to the pad;
providing a mold having a cavity formed by sides, and a gate at a location of one of the sides;
loading the leadframe into the cavity so that the tab is oriented parallel to the side having the gate, and the chip, attached to the leadframe, separates the cavity into a top and a bottom half; and
pressuring molding compound through the gate so that it progresses in flow fronts through the cavity, whereby the tab approximately equalizes the fronts flowing through the top and the bottom cavity half.

16. The method according to claim 15 wherein the tab angle is between about 120° and 160° relative to the planar pad.

17. The method according to claim 15 wherein the tab angle is about 135° relative to the planar pad.

18. The method according to claim 15 wherein the tab height over the pad is between 1 times and 2 times chip thickness.

19. The method according to claim 15 wherein the tab height over the pad is about 1.4 times chip thickness.

20. The method according to claim 15 further including the steps of polymerizing the molding compound and then breaking the molded device package from the mold runner, thereby leaving a surface mark on the device package.

21. A method for fabricating a semiconductor device comprising the steps of:
providing a mold having a cavity formed by sides, and a gate at a corner formed by two adjacent sides;
providing a leadframe having a pad including a planar area and two tabs bent at an angle towards the planar area and reaching a height over the area, the tabs being adjacent to each other;
providing a semiconductor chip having a thickness;
attaching the chip to the pad;
loading the leadframe into the cavity so that the tabs are oriented parallel to the adjacent sides of the cavity corner, and the chip, attached to the leadframe, separates the cavity into a top and a bottom half; and
pressuring molding compound through the gate so that it progresses in flow fronts through the cavity, whereby the tabs approximately equalize the fronts flowing through the top and bottom cavity half.

22. The method according to claim 21 wherein the angle of the tabs is between about 120° and 160° relative to the planar pad.

23. The method according to claim 21 wherein the angle of the tabs is about 135° relative to the planar pad.

24. The method according to claim 21 wherein the height of the tabs over the pad is between 1 times and 2 times chip thickness.

25. The method according to claim 21 wherein the height of the tabs over the pad is about 1.4 times chip thickness.

26. The method according to claim 21 further including the steps of polymerizing the molding compound and then breaking the molded device package from the mold runner, thereby leaving a surface mark on the device package.
